(19) United States
(12) Patent Application Publication
(10) Pub. No.: US 2024/0213400 A1
(43) Pub. Date: Jun. 27, 2024

(54) METHOD FOR INTEGRATING SEMICONDUCTOR CHIPS ON A SUBSTRATE

(71) Applicants: Vikram Shreeshail Turkani, Austin (IN); Vahid Akhavan Attar, Austin, TX (US); Kurt A. Schroder, Austin, TX (US)

(72) Inventors: Vikram Shreeshail Turkani, Austin (IN); Vahid Akhavan Attar, Austin, TX (US); Kurt A. Schroder, Austin, TX (US)

(21) Appl. No.: 18/086,693

(22) Filed: Dec. 22, 2022

(51) Int. Cl. H01L 33/00

(52) U.S. Cl. CPC H01L 33/0093

(57) ABSTRACT

A method for transferring microLEDs from a growth wafer to a display substrate is disclosed. MicroLEDs on the growth wafer are bonded to an adhesive layer on a transparent carrier coated with a light-absorbing layer. After aligning the carrier to a display substrate, the transparent carrier is exposed to light pulses from a flashlamp to heat the light-absorbing layer in order to separate the adhesive layer for the purpose of transferring the microLEDs onto the display substrate. MicroLEDs may be bonded to the display substrate prior to or after transfer to the display substrate. Bonding of the microLEDs to the display substrate, such as soldering, may also be performed with light pulses from the flashlamp by exposing the transparent carrier to heat the light-absorbing layer and the adjacent microLEDs to heat them and bond them to the display substrate.

### TECHNICAL FIELD

The present application relates to semiconductor chips in general, and, in particular, to a method for integrating microchips, such as micro light-emitting diodes (microLEDs) on a substrate.

### BACKGROUND

MicroLED displays are rapidly becoming the dominant technology for small displays because of their wide color gamut, brightness, low power consumption, long lifespan, and environmental stability. MicroLED displays can create amazing visual experiences that are suitable for various applications.

However, there are technical challenges regarding the fabrication of microLED displays. For example, one of the more laborious processes in the fabrication of microLED displays is the transfer of microLEDs from a growth wafer to a display substrate.

Consequently, it would be desirable to improve the transfer speed of microLEDs from a growth wafer to a display substrate with high accuracy in order to promote the mass adoption of microLED displays.

### SUMMARY OF THE INVENTION

In accordance with one embodiment, a group of microLEDs is fabricated on an epi layer located on top of a wafer. The microLEDs are then bonded to a temporary handler via an adhesive layer. The temporary handler is a transparent carrier coated with a light-absorbing layer. A laser beam is applied through the wafer to focus on the epi layer in order to heat the epi layer to release the microLEDs from the wafer, which leaves the microLEDs attaching to the adhesive layer located on the temporary handler. After pressing the microLEDs against a substrate, a set of light pulses from a flashlamp is applied through the transparent carrier in order to heat the light-absorbing layer located on the temporary handler to perform bonding between the microLEDs and metal traces on the substrate. Subsequently, a light pulse from the flashlamp is applied through the transparent carrier in order to release the adhesive layer at the interface of the light-absorbing layer to separate the microLEDs and the adhesive layer from the temporary handler. Next, the adhesive layer is removed to reveal the microLEDs that have been bonded to the substrate.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIGS. 1-7 illustrates a method for transferring microLEDs from a growth wafer to a substrate, according to one embodiment of the present invention.

### DETAILED DESCRIPTION OF A PREFERRED EMBODIMENT

During the fabrication of microLED displays, microLEDs need to be transferred from a growth wafer to a display substrate via the following two steps:
1. Transferring microLEDs from a growth wafer to a temporary handler; and
2. Transferring the microLEDs from the temporary handler to a display substrate containing backplane thin-film transistors (TFTs).

The second step can be achieved by a variety of methods, such as fluidic assembly, laser transfer, roll transfer, and stamp pick-and-place. The fastest ones are laser-based, but the fabrication of even one single large display can take hours. Moreover, additional detection and repair steps are needed to improve the quality of the TFT displays. These additional steps along with the long transfer time are barriers that have prevented microLEDs from mass adoption.

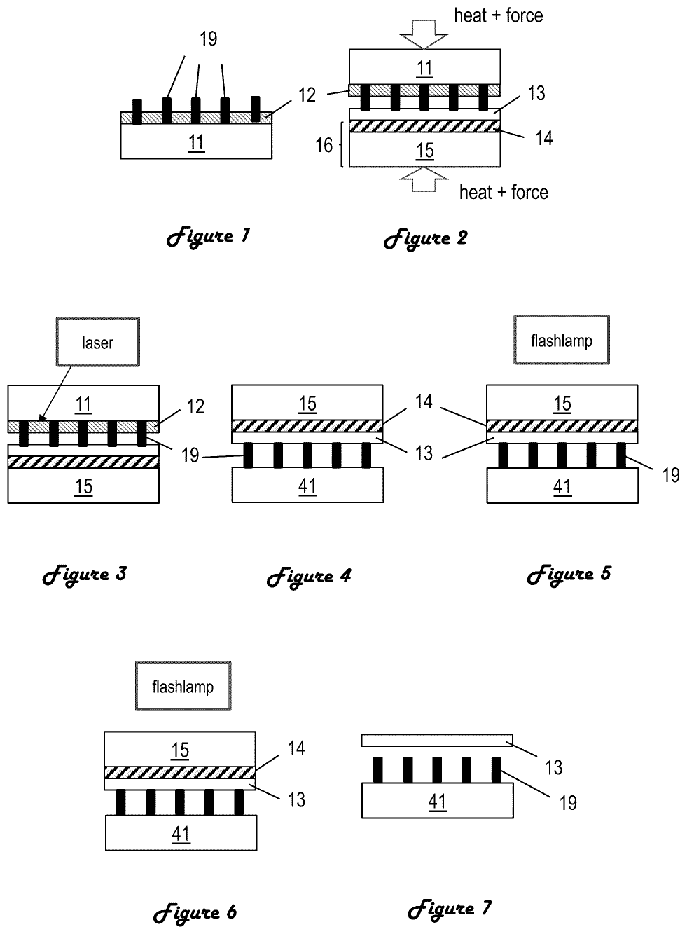

Referring now to the drawings and in particular to FIGS. 1-7, there are depicted an improved method for transferring microLEDs from a growth wafer to a display substrate, according to one embodiment. Initially, microLEDs 19 are fabricated in an epi layer 12 located on top of a growth wafer 11, as shown in FIG. 1. Epi layer 12 can be, for example, a gallium nitride (GaN) epi layer. Growth wafer 11 can be, for example, a sapphire wafer.

### Bond to Temporary Handler

By applying heat and pressure, microLEDs 19 are bonded to a temporary handler 16 via an adhesive layer 13, as depicted in FIG. 2. Temporary handler 16 is a transparent carrier that has been coated with a light-absorbing layer 14 on one side.

Adhesive layer 13 may be applied in liquid form with the aid of a spin-coater to make a uniform, thin adhesive layer over temporary handler 16. It can also be laminated as a tape directly onto temporary handler 16 using heat and pressure.

Light-absorbing layer 14, which is preferably less than 300 nm thick, includes a material that can preferably absorb at least 50% of light pulses having a broadband emission of 200-1500 nm from a flashlamp. Light-absorbing layer 14 is preferably a high-temperature stable material having a coefficient of thermal expansion that is within 50% of transparent carrier 15. Light-absorbing layer 14 may contain titanium, tungsten, molybdenum, carbon, silicon, chromium, oxygen, nitrogen, or a combination of the above-mentioned materials.

Transparent carrier 15 is largely transparent to light pulses (which is a broadband 200-1500 nm emission) from a flashlamp. Exemplary materials for transparent carrier 15 include glasses such as Corning Eagle XG, Schott Borofloat 33, or AGC EN-A1. Quartz or sapphire, acrylic are suitable materials for transparent carrier 15 as well. Transparent carrier 15 can also be made of ceramic.

### Release microLEDs from Growth Wafer

A laser beam from a pulsed ultra-violet (UV) laser is shown through growth wafer 11 and focused on epi layer 12, as shown in FIG. 3, in order to heat epi layer 12 to release microLEDs 19 from growth wafer 11, which leaves microLEDs 19 attaching to adhesive layer on top of temporary handler 16. The UV laser can be a KrF excimer laser operating at 248 nm. The excess epi material from epi layer 12 is subsequently removed from microLEDs 19.

Instead of growing microLEDs 19 on an epi layer, as shown in FIG. 1, microLEDs 19 or other semiconductor microchips can be fabricated on a semiconductor wafer, such as a silicon wafer. After the semiconductor wafer has been adhered to a dicing tape, the semiconductor wafer is diced to obtain microchips. The microchips on the dicing tape are placed and bonded to a temporary handler, such as temporary handler 16, via an adhesive layer using heat and pressure. A backing plate may be placed on the back of dicing tape to apply uniform pressure to adhere the microchips uniformly to temporary handler 16. Temporary handler 16 is a transparent carrier 15 that has been coated with a light-absorbing layer 14 on one side. The dicing tape is subsequently removed and discarded. If this option is employed, the epi steps shown in FIGS. 2-3 can be eliminated.

### Align and Bond microLEDs to Display Substrate

After temporary handler 16 has been aligned with a display substrate 41, microLEDs 19 and/or the microchips from the semiconductor wafer are pressed against display substrate 41, as depicted in FIG. 4. Display substrate 41 includes metal traces and electrical contract points that have been coated with indium or solder. The alignment in FIG. 4 allows microLEDs 19 located on temporary handler 16 to be bonded with display substrate 41 at various electrical contact points.

One method to bond microLEDs 19 located on temporary handler 16 to the electrical contact points of display substrate 41 is by using multiple low-power light pulses from a flashlamp showing through transparent carrier 15 in order to heat light-absorbing layer 14 located on temporary handler 15, as shown in FIG. 5. The heat from light-absorbing layer 14 is conducted through adhesive layer 13 to heat microLEDs 19 to bond them to the various electrical contact points located on display substrate 41, while pressure is being applied.

The flashlamp can be PulseForge Invent model IX2-95-30-PFI (available from PulseForge, Inc.) operating at 250 V to deliver each light pulse for 1,200 microseconds, depositing 0.8 J/cm², at 50 Hz for a total of 200 pulses. The total processing time is approximately 4 seconds, and the total radiant exposure is 160 J/cm². The light pulses from the flashlamp allow microLEDs 19 to be soldered to the various electrical contact points located on display substrate 41.

Alternatively, instead of using light pulse from a flashlamp, microLEDs 19 can be soldered to the various electrical contact points located on display substrate 41 using a reflow 19 oven.

The stack shown in FIG. 5 includes transparent carrier 15 (e.g., Eagle Xg glass, 0.7 mm thick), light-absorbing layer 14 (e.g., sputtered layer of 90% Tungsten/10% Titanium, 200 nm thick), adhesive layer 13 (e.g., PI 2525 from HD microsystems, 25 micron thick), microLEDs 19 (e.g., 0604 metric LEDs, 0.25 mm thick), and display substrate 41 (e.g., borosilicate glass, 0.7 mm thick). 20-micron thick silver traces have been selectively 26 deposited on display substrate 41, and 80-micron thick SAC305 Type 6 solder paste has been selectively deposited on the silver traces at the LED electrical connection points in order to electrically evaluate the success of the chip bonding and release process.

### Release Temporary Handler

After the overall temperature of the stack has been equilibrated, a single light pulse from the flashlamp is shown through transparent carrier 16, as depicted in FIG. 6, in order to release temporary handler 16 at the interface of adhesive layer 13 and light-absorbing layer 14 such that temporary handler 16 can be separated from the stack. This single light pulse from the flashlamp (same as above) is higher power but lower radiant exposure than the aggregate exposure of the light pulses from the bonding step shown in FIG. 5. For this purpose, the 3 flashlamp (same as above) operates at 750 V to deliver the single pulse of light for 300 microseconds, depositing 5.4 J/cm² to release adhesive layer 13 at the interface of adhesive layer 13 and light-absorbing layer 14.

Alternatively, temporary handler 16 can be removed by using a pulsed laser. As pulsed lasers can have much shorter practical pulse lengths over that which is available for a flashlamp, the total radiant exposure can be much lower. This is because there is not time for the heat to diffuse into the carrier and the adhesive during the pulse. The result is that less total energy is required to heat the absorptive layer to the required temperature to release it from the adhesive layer. For an excimer UV laser, the pulse length may be less than a microsecond, the wavelength may be 308 nm, and the total radiant exposure may be less than 250 mJ/cm² for a single pulse. The UV laser may also be a solid-state construction. A pulsed infrared laser may be used instead. As with the UV laser, the pulse length is very short, and the radiant exposure for a given pulse required to release the adhesive is less than 1 J/cm². However, as silicon is somewhat transparent to near infrared to mid infrared wavelengths (1.0-6.0 microns), a silicon wafer may be used as the carrier instead of a glass carrier when using an infrared laser. In the case of both types of pulsed lasers, the beam size is typically much smaller than a flashlamp. Consequently, the beam must be scanned while it is pulsing. A 300 mm wafer may require over 100 individual pulses to cover the entire wafer.

After temporary handler 16 (i.e., transparent carrier 15 and light-absorbing layer 14) has been separated from the stack, adhesive layer 13 is now located at the top of the stack. Adhesive layer 13 is then removed mechanically or by chemical dissolution to reveal microLEDs 19 that are bonded to display substrate 41, as shown in FIG. 7.

Temporary handler 16 may be cleaned of residual adhesive with a variety of chemical or mechanical means and is reusable. An advantage of this invention is that since adhesive layer 13 is never directly exposed to light, the amount of ash present after use is minimal. This makes easy removal of the residual of adhesive layer 13, thus promoting reuse of transparent carrier 15.

If temporary handler 16 has an area larger than the beam of the flashlamp, the flashlamp may be conveyed relative to temporary handler 16-display substrate 41 pair by a motorized stage to synchronize the flashlamp rate to the relative conveyance speed to achieve a uniform exposure over the entire temporary handler 16-display substrate 41 pair. Alternatively, the flashlamp head may be placed on a motorized stage and conveyed similarly while pulsing to achieve a uniform exposure over the entire temporary handler 16-display substrate 41 pair.

The bonding of microLEDs 19 to display substrate 41 may alternatively be performed after the microLED debonding process.

As has been described, the present invention provides an improved method for transferring microLEDs to a display substrate.

In one embodiment, the display substrate is glass. However, if a flexible display is desired, the glass substrate may be replaced by a polymer such as PET, PEN, or PI. Polymers are more thermally fragile than glass, so in order to prevent the polymer substrate from warping during the bonding stage, a heat sink may be placed underneath the polymer. Suitable materials for the heat sink are metal, graphite, ceramic, etc. Preferably, the heat sink is greater than 100 times thicker than the polymer layer, and more preferably greater than 1000 times. When it is desired to fabricate a microLED display on a polymer substrate, this addition is enabling.

Instead of transferring microLEDs to a display substrate, the method of the present invention can be utilized to transfer microchips to a target wafer to form composite microchips or chiplets. A wafer is first adhered to dicing tape, and then the wafer is diced to obtain microchips. The microchips are then picked up individually from the dicing tape and placed, using a pick and place process, onto the adhesive layer that has been deposited on a temporary handler having a transparent carrier coated with a light-absorbing layer.

The exposed surfaces of the placed microchips and the target wafer, which may be a semiconductor wafer, are then cleaned to remove organics and surface oxides and activated in order to bond them together. The microchips are then aligned to the target wafer. Next, both the temporary handler and the target wafer are bonded together by applying heat and pressure in an inert atmosphere.

Heat may be provided to the microchips by using multiple low-power light pulses from a flashlamp showing through transparent carrier in order to heat the light-absorbing layer located on the transparent carrier. The heat from the light-absorbing layer is then conducted through the adhesive layer to heat the microchips and the wafer, while pressure is being applied. As the pressure may be as high as 10-50 MPA, a transparent backing plate may be additionally placed on top of the temporary carrier to increase the stiffness of the transparent carrier.

A flashlamp (same as above) can operate at 250 V to deliver each light pulse for 1,200 microseconds, depositing 0.8 J/cm², at 50 Hz for a total of 400 pulses. The total processing time is approximately 8 seconds, and the total radiant exposure is 320 J/cm². This bonding process, referred to as hybrid bonding, is performed under inert gas atmosphere such as nitrogen or argon or a combination thereof. This results in a bond formed between semiconductor materials and also between metal traces present on the surfaces of the microchips and the target wafer. The bonds are non-metal to non-metal and metal-to-metal nature. Alternatively, the microchips and wafers can be bonded by applying pressure between then in an oven under inert atmosphere.

While the invention has been particularly shown and described with reference to a preferred embodiment, it will be understood by those skilled in the art that various changes in form and detail may be made therein without departing from the spirit and scope of the invention.

What is claimed is:

1. A method for transferring microLEDs from a growth wafer to a display substrate, said method comprising:
bonding a plurality of microLEDs fabricated on an epi layer located on top of a growth wafer to a temporary handler via an adhesive layer, wherein said temporary handler is a transparent carrier coated with a light-absorbing layer;
applying a laser beam through said growth wafer to heat said epi layer in order to release said microLEDs from said growth wafer, which leaves said microLEDs attaching to said adhesive layer located on said temporary handler;
aligning and pressing said microLEDs located on said temporary handler against a plurality of electrical contact points on a display substrate;
applying a plurality of light pulses through said transparent carrier to heat said light-absorbing layer located on said temporary handler in order to bond said microLEDs and said electrical contact points on said display substrate;
applying a light pulse through said transparent carrier in order to separate said temporary handler from said adhesive layer at the interface of said light-absorbing layer and said adhesive layer;
removing said adhesive layer to reveal said microLEDs that have been bonded to said display substrate.

2. The method of claim 1, wherein said electrical contact points on said microLEDs and display substrate are coated with indium.

3. The method of claim 1, wherein said electrical contact points on said display substrate are coated with solder.

4. The method of claim 1, wherein said light-absorbing layer includes titanium, tungsten, molybdenum, carbon, silicon, chromium, oxygen, nitrogen or a combination thereof.

5. The method of claim 1, wherein said step of applying a plurality of light pulses further includes applying said plurality of light pulses via a flashlamp through said transparent carrier to heat said light-absorbing layer.

6. The method of claim 1, wherein said step of removing said adhesive layer further includes removing said adhesive layer mechanically or chemically.

7. A method for transferring microchips from a wafer to a receiving substrate, said method comprising:
adhering a wafer onto a dicing tape;
after said wafer has been diced to form a plurality of microchips, adhering said microchips to a temporary handler via an adhesive layer, wherein said temporary handler is a transparent carrier coated with a light-absorbing layer;
aligning and pressing said microchips on said temporary handler against a plurality of electrical contact points on a receiving substrate;
applying a plurality of light pulses through said transparent carrier to heat said light-absorbing layer located on said temporary handler in order to bond said microchips to said electrical contact points on said receiving substrate;
applying a light pulse through said transparent carrier in order to separate said temporary handler from said adhesive layer at the interface of said light-absorbing layer and said adhesive layer; and
removing said adhesive layer to reveal said microchips that have been bonded to said receiving substrate.

8. The method of claim 7, wherein said electrical contact points on said receiving substrate are coated with indium.

9. The method of claim 7, wherein said electrical contact points on said receiving substrate are coated with solder.

10. The method of claim 7, wherein said light-absorbing layer includes titanium, tungsten, molybdenum, carbon, silicon, chromium, oxygen, nitrogen or a combination thereof.

11. The method of claim 7, wherein said step of applying a plurality of light pulses further includes applying said plurality of light pulses via a flashlamp through said transparent carrier to heat said light-absorbing layer.

12. A method for transferring microchips from a wafer to a target wafer, said method comprising:
adhering a wafer onto a dicing tape;
after said wafer has been diced into a plurality of microchips, individually placing each of said microchips from said dicing tape onto a temporary handler having an adhesive layer via a pick-and-place process, wherein said temporary handler is a transparent carrier coated with a light-absorbing layer;
aligning and pressing said microchips on said temporary handler against a plurality of electrical contact points on a target wafer;
applying a plurality of light pulses through said transparent carrier to heat said light-absorbing layer located on said temporary handler in order to bond said microchips to said electrical contact points on said target wafer;
applying a light pulse through said transparent carrier in order to separate said temporary handler from said adhesive layer at the interface of said light-absorbing layer and said adhesive layer; and
removing said adhesive layer to reveal said microchips that have been bonded to said target wafer.

13. The method of claim 12, wherein said electrical contact points on said target wafer are coated with indium.

14. The method of claim 12, wherein said electrical contact points on said target wafer are coated with solder.

15. The method of claim 12, wherein said light-absorbing layer includes titanium, tungsten, molybdenum, carbon, silicon, chromium, oxygen, nitrogen or a combination thereof.

16. The method of claim 12, wherein said step of applying a plurality of light pulses further includes applying said plurality of light pulses via a flashlamp through said transparent carrier to heat said light-absorbing layer.

17. The method of claim 12, wherein said step of placing further includes cleaning and activating exposed surfaces of said placed microchips and a target wafer.
